(19) United States
(12) Patent Application Publication
(10) Pub. No.: US 2008/0003773 A1
(43) Pub. Date: Jan. 3, 2008

(54) Method for forming isolation structure of semiconductor device

(76) Inventors: Sang-Hyon Kwak, Kyoungki-do (KR); Su-Hyun Lim, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/647,635

(22) Filed: Dec. 28, 2006

(30) Foreign Application Priority Data
Jun. 29, 2006 (KR) 10-2006-0059597

(51) Int. Cl. H01L 21/76

(52) U.S. Cl. 438/425; 257/E21.54

(57) ABSTRACT

A method for forming an isolation structure of a semiconductor device including a substrate where a gate insulating layer, a gate conductive layer, and a pad nitride layer are already formed includes etching the pad nitride layer, the gate conductive layer, the gate insulating layer and a portion of the substrate to form a trench, forming a wall oxide layer along an inner surface of the trench, forming a first insulating layer over a first resulting structure, including the wall oxide layer, to partially fill the trench, forming a second insulating layer using a spin coating method over a second resulting structure, including the first insulating layer, to fill the trench, polishing the first and second insulating layers using the pad nitride layer as a polish stop layer, removing the pad nitride layer, recessing the first and second insulating layers, and recessing the second insulating layer to a predetermined depth.

### CROSS-REFERENCE TO RELATED APPLICATIONS

The present invention claims priority of Korean patent application number 10-2006-0059597, filed on Jun. 29, 2006, which is incorporated by reference in its entirety.

### BACKGROUND OF THE INVENTION

The present invention relates to a method for fabricating a semiconductor device, and more particularly, to a method for forming an isolation structure of a semiconductor device.

As a semiconductor fabrication technology is advanced, the line width of a semiconductor device decreases. Specifically, the line width of a field region defined between active regions decreases and thus an aspect ratio of a trench formed in the field region increases. Consequently, a process of filling the trench to form an isolation structure becomes difficult.

In order to improve the filling characteristic of the isolation structure, the trench is filled with polysilazane (PSZ), instead of high density plasma (HDP) undoped silicate glass (USG). The PSZ is a kind of spin on dielectric (SOD) deposited by spin coating. However, a wet etch rate of the PSZ is fast and non-uniform. Thus, when a wet etching process is performed, an effective field oxide height (EFH) becomes non-uniform.

To solve these limitations, a trench is filled with a PSZ layer and recessed to a predetermined depth and then an HDP USG layer is deposited over the resulting structure. This method will be described below with reference to FIGS. 1A to 1L.

FIGS. 1A to 1L illustrate a typical method for forming an isolation structure of a flash memory device. Referring to FIG. 1A, a gate oxide layer 2, a polysilicon layer 3 for a gate electrode (a floating gate), a buffer oxide layer 4, a pad nitride layer 5, and an oxide layer 6 for a hard mask are sequentially formed over a substrate 1. Referring to FIG. 1B, the oxide layer 6, the pad nitride layer 5, the buffer oxide layer 4, the polysilicon layer 3, the gate oxide layer 2, and the substrate 1 are etched to a predetermined depth to form a trench 7. Referring to FIG. 1C, an oxidation process is performed to form a wall oxide layer 8 along an inner surface of the trench 7. Referring to FIG. 1D, an HDP USG layer 9 (hereinafter, referred to as an HDP layer) is deposited over the resulting structure, including the wall oxide layer 8, to fill a portion of the trench 7. Referring to FIG. 1E, a PSZ layer 10 is formed over the resulting structure, including the HDP layer 9, to completely fill the trench 7.

Referring to FIG. 1F, a chemical mechanical polishing (CMP) process is performed to remove the oxide-based materials formed over the pad nitride layer 5. That is, the CMP process is performed to remove the PSZ layer 10, the HDP layer 9, and the oxide layer 6 by using the pad nitride layer 5 as a polish stop layer. A cleaning process is performed to remove oxide-based materials remaining on the pad nitride layer 5. A thickness of the PSZ layer 10 is somewhat reduced by the cleaning process. As illustrated, the PSZ layer 10 has a profile lower than the pad nitride layer 5. Referring to FIG. 1G, a wet etching process is performed to recess the PSZ layer 10 to a predetermined depth.

Referring to FIG. 1H, an HDP layer 11 is deposited over the resulting structure, including the PSZ layer 10, to fill the trench 7. This process compensates the EFH that is not optimized because the PSZ layer 11 is rapidly etched during the previous wet etching process. Referring to FIG. 1I, a CMP process is performed to polish the HDP layer 11 up to a top surface of the pad nitride layer 5. Consequently, an isolation structure 12 buried in the trench is formed. Referring to FIG. 1J, the pad nitride layer 5 is removed using phosphoric acid (H₃PO₄) solution. A wet etching process or a dry etching process is performed to recess the HDP layer 11 to a predetermined depth. At this time, the buffer oxide layer 4 is also removed. Consequently, an isolation structure 12A is formed.

Referring to FIG. 1K, an insulating layer for spacers is deposited over the polysilicon layer 3, including the recessed HDP layer 11. An etch back process is performed to form spacers 13 on both sidewalls of the polysilicon layer 3. During the etch back process, a predetermined thickness of the HDP layer 11 exposed along a profile of the spacers 13 is lost while forming the spacers 13. A portion of the isolation structure 12B between the adjacent polysilicon layers 3 is recessed to a predetermined depth. This makes it possible to prevent interference caused by parasitic capacitance occurring due to a narrow gap between the adjacent polysilicon layers 3. This interference means interference between flash memory cells. Referring to FIG. 1L, a wet etching process is performed to remove the spacers 13.

The typical method for forming the isolation structure of the flash memory device has the following limitations. As illustrated in FIG. 1B, the trench 7 is formed by etching the oxide layer 6 for the hard mask, the pad nitride layer 5, the buffer oxide layer 4, the polysilicon layer 3, the gate oxide layer 2, and the substrate 1 by a predetermined depth. Thus, the aspect ratio of the trench 7 is high. In FIG. 1H, when the HDP layer 11 is deposited in the trench 7 having the high aspect ratio, void may be formed inside the HDP layer 11. Also, because the polysilicon layer 3 is exposed to the inside of the trench when the HDP layer 11 is deposited, the polysilicon layer 3 may be damaged during the deposition process.

As described above with reference to FIGS. 1F and 1I, the CMP process is performed two times. The two-time CMP process may cause a dishing of the HDP layer 11 and may cause an excessive loss of the pad nitride layer 5. The dishing means that the HDP layer 11 is more recessed than other portions because a polishing amount of the HDP layer 11 increases.

As described above with reference to FIG. 1K, when the spacers are formed for suppressing the interference between the adjacent memory cells, the isolation structure is recessed to a predetermined depth and thus the EFH is changed. Moreover, because the process of removing the spacers must be performed, the overall process becomes complicated.

### SUMMARY OF THE INVENTION

One embodiment of the present invention is directed to provide a method for forming an isolation structure of a semiconductor device, which can improve a filling characteristic degraded by an increased aspect ratio of an isolation structure.

Another embodiment of the present invention is directed to provide a method for forming an isolation structure of a semiconductor device, which can prevent an excessive loss of a pad nitride layer used to form an isolation structure.

A further another embodiment of the present invention is directed to provide a method for forming an isolation structure of a semiconductor device, which can simplify a fabricating process and prevent interference between adjacent cells.

In accordance with an aspect of the present invention, there is provided a method for forming an isolation structure of a semiconductor device including a substrate where a gate oxide layer, a gate conductive layer, and a pad nitride layer are already formed, the method including: etching the pad nitride layer, the gate conductive layer, the gate oxide layer and a portion of the substrate to form a trench; forming a wall oxide layer along an inner surface of the trench; forming a first insulating layer over a first resulting structure, including the wall oxide layer, to partially fill the trench; forming a second insulating layer using a spin coating method over a second resulting structure, including the first insulating layer, to fill the trench; polishing the first and second insulating layers using the pad nitride layer as a polish stop layer; removing the pad nitride layer; recessing the first and second insulating layers; and recessing the second insulating layer to a predetermined depth.

### BRIEF DESCRIPTION OF THE DRAWINGS

FIGS. 1A to 1L illustrate cross-sectional views showing a typical method for forming an isolation structure of a semiconductor device.

FIGS. 2A to 2G illustrate cross-sectional views showing a method for forming an isolation structure of a semiconductor device in accordance with one embodiment of the present invention.

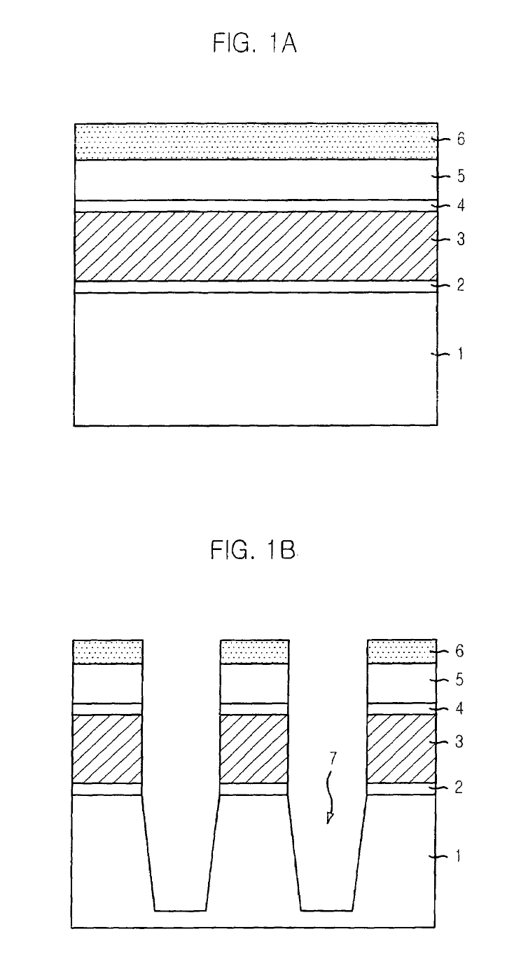

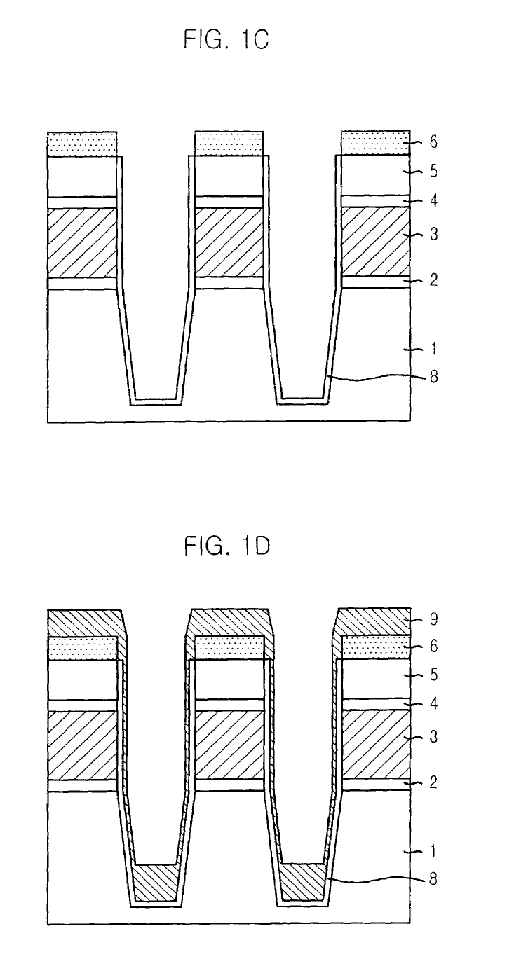

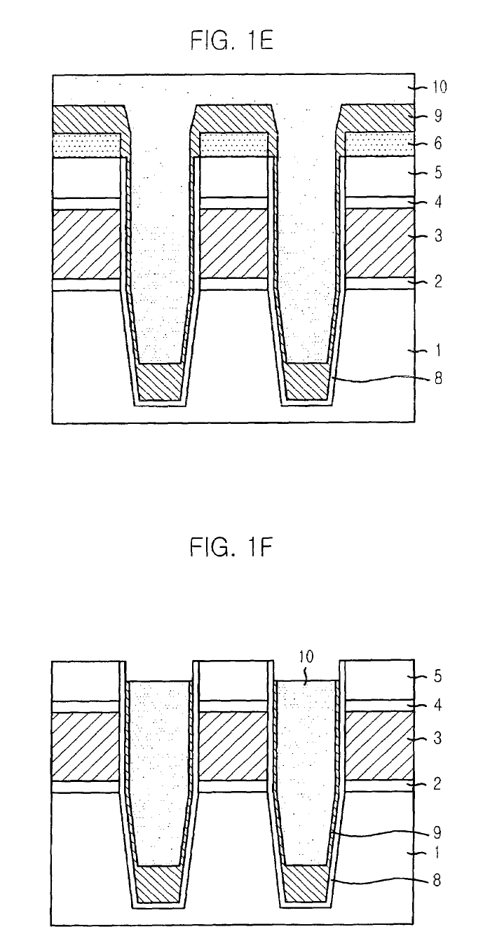

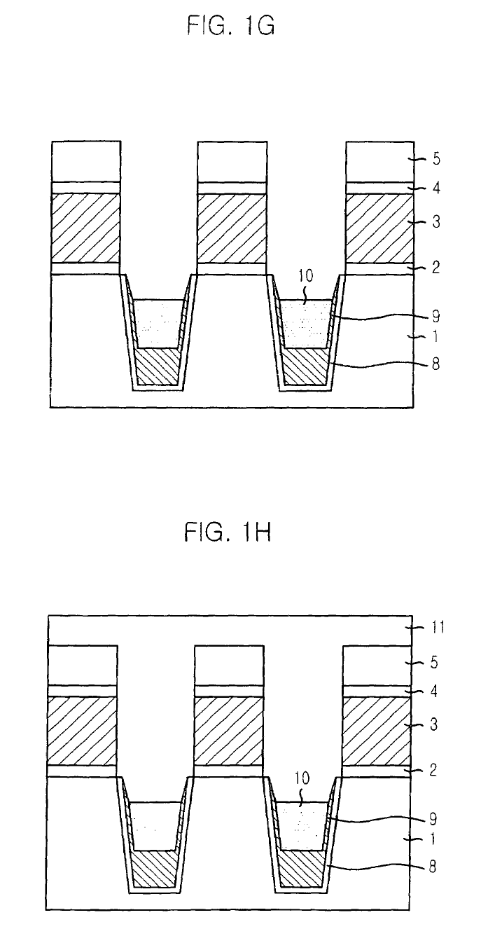

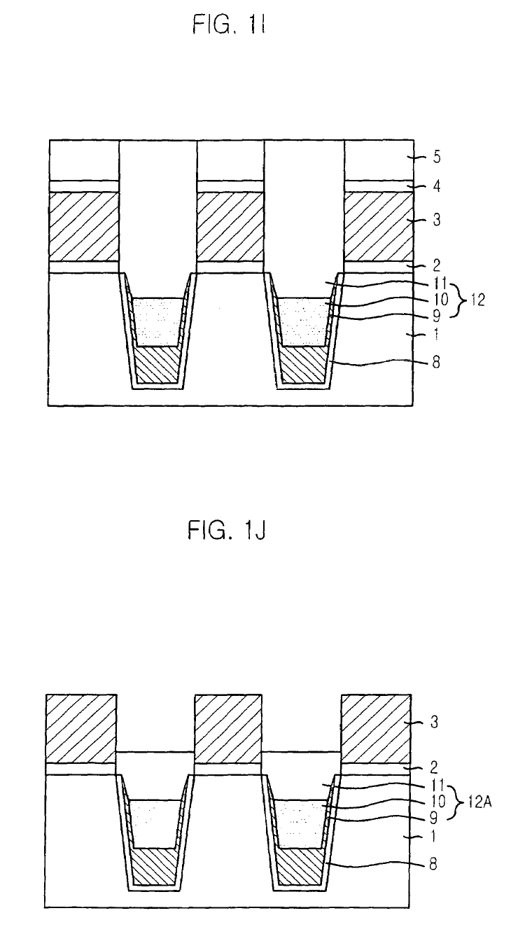

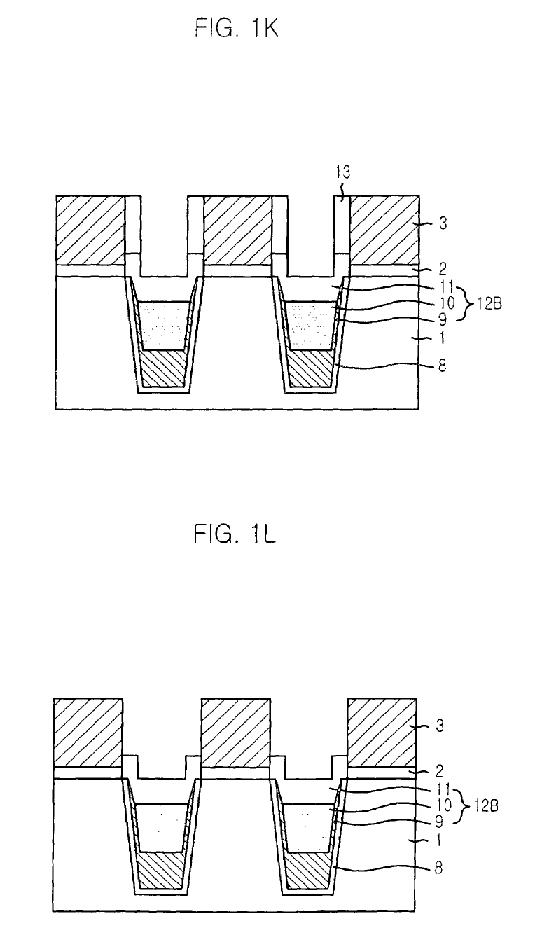

### DESCRIPTION OF SPECIFIC EMBODIMENTS

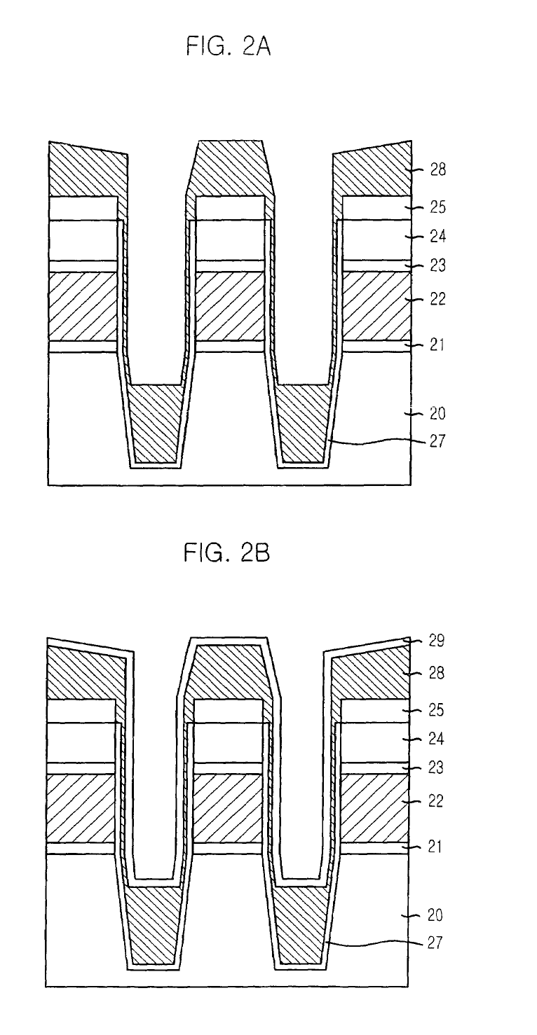

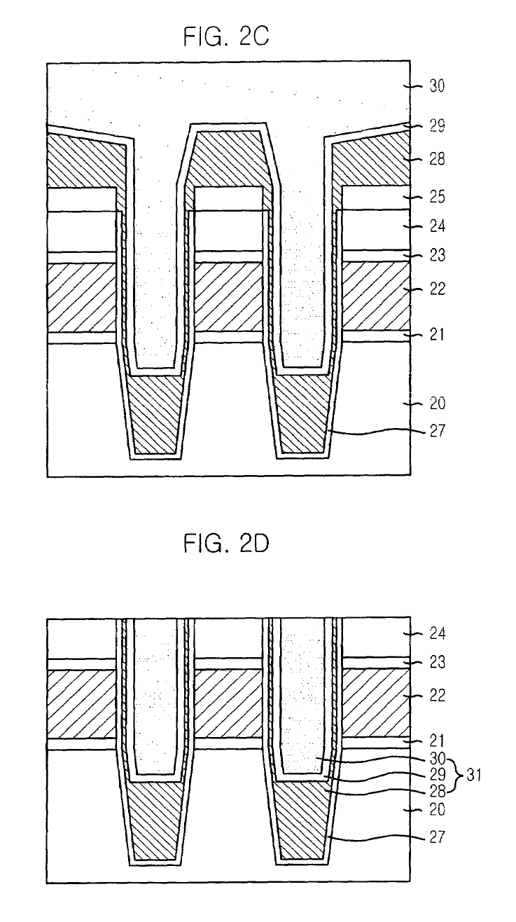

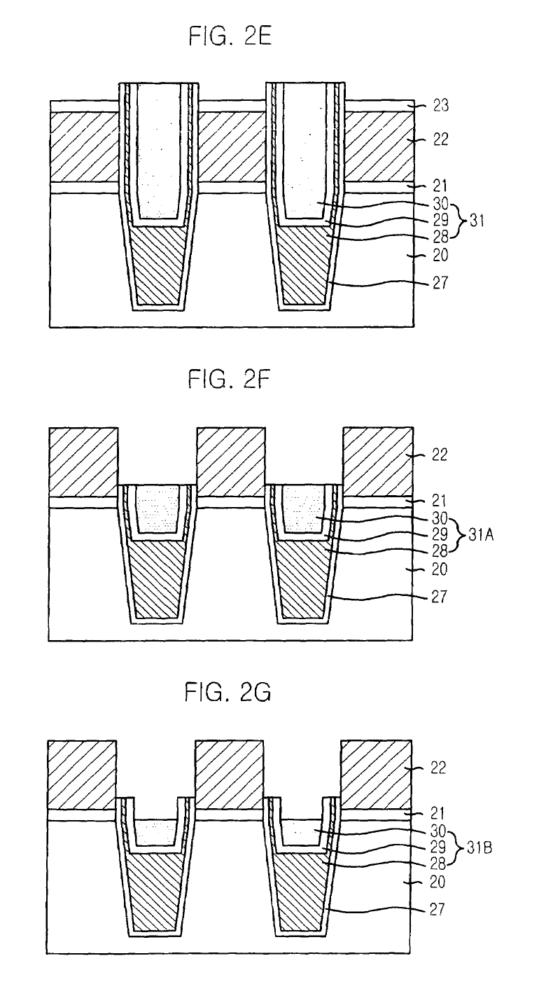

FIGS. 2A to 2G illustrate cross-sectional views showing a method for forming an isolation structure of a semiconductor device in accordance with one embodiment of the present invention. Specifically, FIGS. 2A to 2G illustrate a method for forming an isolation structure of a flash memory device.

Referring to FIG. 2A, a gate insulating layer 21, a polysilicon layer 22 for a gate electrode (a floating gate), a buffer oxide layer 23, a padding layer 24, and an oxide layer 25 for a hard mask are sequentially formed over a substrate 20. The gate insulating layer 21 includes an oxide-based material and the padding layer 24 includes a nitride-based material. Hereinafter, the gate insulating layer 21 and the padding layer 24 are referred to as the gate oxide layer 21 and the pad nitride layer 24, respectively. The oxide layer 25 for the hard disk is etched using a predetermined photoresist pattern. A trench (not shown) is formed by etching the pad nitride layer 24, the buffer oxide layer 23, the polysilicon layer 22, the gate oxide layer 21, and the substrate 20 to a predetermined depth using the etched oxide layer 25. An oxidation process is performed to form an oxide layer 27 along an inner surface of the trench. Hereinafter, the oxide layer 27 is referred to as the wall oxide layer 27.

An HDP layer 28 is deposited for insulation over the resulting structure, including the wall oxide layer 27, to fill a portion of the trench. To secure a filling characteristic, the HDP layer 28 is deposited to a thickness ranging from approximately 800 Å to approximately 1,500 Å as a whole and a thickness ranging from approximately 70 Å to approximately 150 Å at the sidewalls of the wall oxide layer 27.

Referring to FIG. 2B, a high temperature oxide (HTO) layer 29 is deposited for insulation over the HDP layer 28 having a height difference. At this time, the HTO layer 29 is deposited to a thickness ranging from approximately 100 Å to approximately 300 Å by a low pressure chemical vapor deposition (LPCVD) process.

Referring to FIG. 2C, a PSZ layer 30 is deposited for insulation over the HTO layer 29 to completely fill the trench (not shown). The PSZ layer 30 is deposited to a thickness ranging from approximately 4,000 Å to approximately 7,000 Å. The PSZ layer 30 is deposited using a spin coating method. Therefore, when the HDP layer is deposited in the trench having a high aspect ratio, the generation of a void can be prevented. Like in the deposition of the HDP layer 28, the wall oxide layer 27 is formed in the sidewalls of the polysilicon layer 22 before depositing the PSZ layer 30, preventing the damage of the polysilicon layer 22.

Referring to FIG. 2D, a CMP process is performed to remove oxide-based materials formed over the pad nitride layer 24. Because the CMP process is performed using the pad nitride layer 24 as a polish stop layer, oxide-based materials formed on the pad nitride layer 24 are all removed. When a cleaning process is performed during the CMP process, a cleaning process using hydrogen fluoride (HF) is not performed in order to prevent the loss of the PSZ layer 30. As a result, an isolation structure 31 flush with the pad nitride layer 24 is formed. Because the CMP process is performed one time, it is possible to prevent the loss of the isolation structure 31 caused by dishing and the loss of the pad nitride layer 24.

Referring to FIG. 2E, a cleaning process or a dry cleaning process is performed to etch the HDP layer 28, the HTO layer 29, and the PSZ layer 30 by a predetermined thickness. At this time, the cleaning process is performed using a cleaning solution having a low selectivity, that is, a cleaning solution having almost no etch selectivity difference with respect to the HDP layer 28, the HTO layer 29, and the PSZ layer 30. The cleaning process using the cleaning solution having a low selectivity aims to prevent the increasing etch loss of the PSZ layer 30 due to the wet etch selectivity difference with respect to the HDP layer 28, the HTO layer 29, and the PSZ layer 30. A wet etching process using phosphoric acid solution (H₃PO₄) is performed to remove the pad nitride layer 24. Consequently, the isolation structure 31 protrudes over the buffer oxide layer 23 by a predetermined thickness.

Referring to FIG. 2F, a dry etching process is performed to recess the isolation structure 31A to a predetermined depth. The reason why the dry etching process is performed is that the PSZ layer 30 is easily etched by the wet etching process. Because an HDP layer need not be further deposited in order to optimize the EFH, the fabricating process can be simplified.

During the dry etching process, the isolation structure 31A is recessed until its height from the top surface of the gate oxide layer 21 ranges from approximately 100 Å to approximately 300 Å. At this time, the buffer oxide layer 23 is also removed. Meanwhile, the dry etching process is performed using an etching gas having a high etch selectivity with respect to the polysilicon layer 22 in order not to damage the polysilicon layer 22 exposed by the recessing process of the isolation structure 31A.

Referring to FIG. 2G, a wet etching process is performed to selectively recess the PSZ layer 30 to a predetermined depth. As a result, a portion of the isolation structure 31B is recessed so that its height is smaller than that of the gate oxide layer 21. This wet etching process aims to selectively wet-etch the PSZ layer 30 using the fact that the PSZ layer 30 has a relatively higher wet etch selectivity than the HTO layer 29 and the HDP layer 28. The PSZ layer 30 is etched and recessed by a thickness ranging from approximately 200 Å to approximately 600 Å.

In accordance with the present invention, parasitic capacitance between the adjacent polysilicon layers 22 can be eliminated by recessing a portion of the isolation structure 31B formed between the adjacent polysilicon layers 22 to a predetermined depth. Therefore, the interference between the adjacent cells is prevented, improving the device characteristics. Specifically, because a portion of the isolation structure 31B is recessed to a predetermined depth by using the high wet etching property of the PSZ layer 30, a process of forming and removing spacers need not be performed, thereby simplifying the fabricating process.

The present invention can obtain the following effects. First, because the PSZ layer formed by the spin coating method is used as a final trench filling material, it is possible to prevent voids from being formed in the trench having a high aspect ratio. Second, because the wall oxide layer is formed in the sidewalls of the polysilicon layer when the PSZ layer is deposited as a final trench filling material, it is possible to prevent the polysilicon layer form being damaged during the deposition process. Third, because the isolation structure buried in the trench is formed by a one-time CMP process, it is possible to prevent the loss of the isolation structure due to dishing and the loss of the pad nitride layer. Fourth, the isolation structure is formed using the HDP layer, the HTO layer, and the PSZ layer and is recessed to a predetermined depth by the dry etching process. Then, the PSZ layer is selectively removed by the wet etching process. Therefore, the fabricating process is simplified and the parasitic capacitance between the adjacent polysilicon layers for the floating gate can be minimized. Consequently, the interference between the adjacent cells can be suppressed.

While the present invention has been described with respect to the specific embodiments, it will be apparent to those skilled in the art that various changes and modifications may be made without departing from the spirit and scope of the invention as defined in the following claims.

What is claimed is:

1. A method for forming an isolation structure of a semiconductor device including a substrate where a gate insulating layer, a gate conductive layer, and a padding layer are already formed, the method comprising:
etching the padding layer, the gate conductive layer, the gate insulating layer and a portion of the substrate to form a trench;
forming an oxide layer along an inner surface of the trench;
forming a first insulating layer over a first resulting structure, including the oxide layer, to partially fill the trench;
forming a second insulating layer using a spin coating method over a second resulting structure, including the first insulating layer, to fill the trench;
polishing the first and second insulating layers using the padding layer as a polish stop layer;
removing the padding layer;
recessing the first and second insulating layers; and
recessing the second insulating layer to a predetermined depth.

2. The method of claim 1, wherein the second insulating layer comprises a polysilazane (PSZ).

3. The method of claim 1, wherein the first insulating layer comprises a high density plasma (HDP) layer.

4. The method of claim 1, further comprising, after forming the first insulating layer, forming a third insulating layer over a height difference of the second resulting structure including the first insulating layer.

5. The method of claim 4, wherein the third insulating layer comprises a high temperature oxide (HTO) layer.

6. The method of claim 1, further comprising, after polishing the first and second insulating layers, performing a cleaning process.

7. The method of claim 6, wherein the cleaning process comprises performing wet cleaning or dry cleaning, the wet cleaning using a cleaning solution having a low etch selectivity between the first and second insulating layers.

8. The method of claim 1, wherein the recessing of the first and second insulating layers comprises performing a dry etching process.

9. The method of claim 1, wherein the recessing of the first and second insulating layers comprises recessing the first and second insulating layers to have top surfaces of the first and second insulating layers higher than a top surface of the gate insulating layer.

10. The method of claim 1, wherein the recessing of the first and second insulating layers comprises performing a dry etching process.

11. The method of claim 1, wherein the recessing of the first and second insulating layers comprises recessing the first and second insulating layers to have top surfaces of the first and second insulating layers higher than a top surface of the gate insulating layer by approximately 100 Å to approximately 300 Å.

12. The method of claim 1, wherein the recessing of the second insulating layer comprises recessing the second insulating layer to have a top surface of the second insulating layer lower than a top surface of the gate insulating layer.

13. The method of claim 1, wherein the recessing of the second insulating layer comprises recessing the second insulating layer by a thickness ranging from approximately 200 Å to approximately 600 Å.

14. The method of claim 1, wherein the forming of the first insulating layer comprises forming the first insulating layer over the sidewalls of the trench to a thickness ranging from approximately 70 Å to approximately 150 Å.

15. The method of claim 1, wherein the gate insulating layer comprises an oxide-based material.

16. The method of claim 1, wherein the padding layer comprises a nitride-based material.
